(19) United States
(12) Patent Application Publication
(10) Pub. No.: US 2010/0193130 A1
(43) Pub. Date: Aug. 5, 2010

(54) PLASMA PROCESSING APPARATUS

(76) Inventors: Masatoshi KAWAKAMI, Kudamatsu (JP); Tooru ARAMAKI, Kudamatsu (JP); Shigeru SHIRAYONE, Shunan (JP); Kenetsu YOKOGAWA, Tsurugashima (JP); Takumi TANDOU, Asaka (JP)

Correspondence Address: MCDERMOTT WILL & EMERY LLP, 600 13TH STREET, N.W., WASHINGTON, DC, 20005-3096, US

(21) Appl. No.: 12/393,272

(22) Filed: Feb. 26, 2009

(30) Foreign Application Priority Data
Feb. 4, 2009 (JP) 2009-023202

(51) Int. Cl. H01L 21/306

(52) U.S. Cl. 156/345.37

(57) ABSTRACT

In a plasma processing apparatus including a vacuum chamber, a sample table for mounting a member to be processed thereon, the sample table having a coolant path to control a temperature of the member to be processed, an electrostatic chuck power supply for electrostatically adsorbing the member to be processed on the sample table, and a plurality of gas hole parts provided in the sample table to supply heat transfer gas between the member to be processed and the sample table and thereby control a temperature of the member to be processed, each of the gas hole parts includes a boss formed of a dielectric, a sleeve, and a plurality of small tubes, and the small tubes are arranged in a range of 10 to 50% of a radius when measured from a center of the gas hole part toward outside.

### BACKGROUND OF THE INVENTION

The present invention relates to a plasma processing apparatus which conducts processing on a member to be processed such as a semiconductor wafer, and in particular to a plasma processing apparatus in which abnormal discharge is suppressed between the member to be processed and a sample stage which holds the member to be processed.

In a plasma processing apparatus used in the manufacturing process of semiconductor devices, temperature control on the member to be processed is important in making the etching rate which influences the yield uniform. Therefore, a sample table for mounting the member to be processed thereon is subject to temperature control, and heat transfer gas such as helium is introduced between the sample table and the member to be processed. In addition, temperature control is exercised so as to make the temperature uniform over the whole of the member to be processed. The member to be processed is adsorbed on ceramics by applying a voltage to the sample table having ceramics (electrostatic chuck plate) on its top surface. Several gas holes are provided in the sample table to supply gas. A plurality of grooves taking the shape of concentric circles for gas dispersion are formed to cause the heat transfer gas from the gas holes to reach all across the back of the member to be processed easily. The gas holes penetrate the ceramics and reach the inside of the conductive sample table.

The environment involving high frequency power required to process the member to be processed during the plasma processing and heat transfer gas pressure of several kPa required for temperature control is an environment which is apt to cause discharge in the gas holes. For preventing the discharge, it is necessary to form a gas hole part of a dielectric so as to prevent a conductor part from being exposed to the gas hole and narrow the gas hole space according to the Paschen's law so as to prevent abnormal discharge from being generated easily.

Under these circumstances, a plasma processing apparatus in which the gas hole part is formed of a dielectric and a plurality of linear holes each having a minute diameter are formed through the dielectric to narrow the space of the gas hole is disclosed in, for example, JP-A-10-50813 (corresponding to U.S. Pat. No. 5,720,818) and JP-A-2006-344766.

### SUMMARY OF THE INVENTION

In the above-described related art, however, only insulating by using the dielectric in the gas hole part and narrowing the space of the gas hole are taken into consideration, but the electric field distribution in the vicinity of the actual outlet of the gas hole part is not taken into consideration. Therefore, the related art is insufficient as a countermeasure against the abnormal discharge.

An electric field in the gas hole part intrudes into the inside from the vicinity of the outlet of the gas hole part which penetrates the conductor to the inside to some extent. As shown in FIG. 1A, the electric field distribution formed from the outlet of the gas hole part toward the inside extends so as to make electric lines of force diverge in the depth direction. The cause for formation of the electric field distribution in the depth direction is that a potential difference Vd between a self-bias potential Vs generated on the member to be processed by high frequency power and a potential Ve applied in order to electrostatically adsorb the member to be processed on the sample table, i.e., Vd=Vs−Ve is generated between the member to be processed and the sample table. In other words, even if the gas hole part is formed of the dielectric and the space of the gas hole is narrowed by using holes having a minute diameter, electrons are accelerated in the depth direction in the gas hole located near the center of the gas hole part, and consequently there is a sufficient space required for discharge and abnormal discharge occurs.

The electric field distribution forms equipotential lines as shown in FIG. 1B. It is appreciated from FIG. 1B that equipotential lines are dense and the electric field strength is strong in the vicinity of the periphery. If there is a gas hole near the periphery part, therefore, abnormal discharge occurs.

In other words, in both the related art described in JP-A-10-50813 and that described in JP-A-2006-344766, gas holes are opened in the vicinity of the center of the gas hole part and in the vicinity of the peripheral part of the gas hole part, and a problem that the abnormal discharge cannot be prevented sufficiently occurs.

In view of the drawbacks of the related art, an object of the present invention is to provide a plasma processing apparatus in which the suppression effect of abnormal discharge is enhanced by optimizing locations of a plurality of gas holes provided in the gas hole part.

The present invention provides a plasma processing apparatus including a vacuum chamber, a sample table for mounting a member to be processed thereon, the sample table having a coolant path to control a temperature of the member to be processed, an electrostatic chuck power supply for electrostatically adsorbing the member to be processed on the sample table, and a plurality of gas hole parts provided in the sample table to supply heat transfer gas between the member to be processed and the sample table and thereby control a temperature of the member to be processed, wherein each of the gas hole parts includes a boss formed of a dielectric, a sleeve, and a plurality of small tubes, and the small tubes are arranged in a range of 10 to 50% of a radius when measured from a center of the gas hole part toward outside.

Each of the gas hole parts further includes a strut formed of a dielectric, and the strut is disposed under the boss so as to form a gap between the strut and the boss and another gap between the strut and the sleeve, and the heat transfer gas flows through the gaps.

Since electric lines of force diverge, the acceleration direction of electrons has an inclination in the radial direction as the location goes away from the vicinity of the center. Electrons are accelerated in the direction of gas hole side wall by separating the location of each gas hole from the center of the gas hole part to the outside by at least 10% of the radius. As a result, the effective discharge space is narrowed and abnormal discharge can be suppressed.

In addition, if the location of each gas hole is set equal to 50% or less of the radius when measured from the center of the gas hole part toward the outside, then the electric field strength reduces to one-third or less as compared with the vicinity of the periphery of the gas hole part, and consequently abnormal discharge can be suppressed.

According to the present invention, abnormal discharge can be prevented from occurring in gas holes by disposing all of the gas holes in the range of 10 to 50% of the radius when measured from the center of the gas hole part toward the outside. Furthermore, it is possible to prevent the sample table from being damaged by the abnormal discharge and consequently improve the reliability and stability of the apparatus.

Other objects, features and advantages of the invention will become apparent from the following description of the embodiments of the invention taken in conjunction with the accompanying drawings.

### BRIEF DESCRIPTION OF THE DRAWINGS

FIGS. 1A and 1B are diagrams showing a section and electric field distribution of a conventional gas hole part;

FIG. 2 is a schematic diagram of a plasma processing apparatus according to a first embodiment of the present invention;

FIG. 3 is a sectional view of an electrode according to the first embodiment of the present invention;

FIG. 4 is an oblique view of the electrode according to the first embodiment of the present invention;

FIG. 5 is a sectional view of a gas hole part according to the first embodiment of the present invention;

FIG. 6 is a top view of the gas hole part according to the first embodiment of the present invention;

FIG. 7 is a diagram showing a flow of heat transfer gas in the gas hole part according to the first embodiment of the present invention;

FIG. 8 is a diagram showing electric field distribution in the gas hole part according to the first embodiment of the present invention by using electric lines of force;

FIG. 9 is a diagram showing the Paschen's law which prescribes an abnormal discharge start voltage as a function of a product of pressure and a hole diameter;

FIG. 10 is a sectional view of a gas hole part according to a second embodiment of the present invention;

FIG. 11 is a diagram showing a flow of heat transfer gas in the gas hole part according to the second embodiment of the present invention; and

FIG. 12 is a diagram showing electric field distribution in the gas hole part according to the second embodiment of the present invention by using electric lines of force.

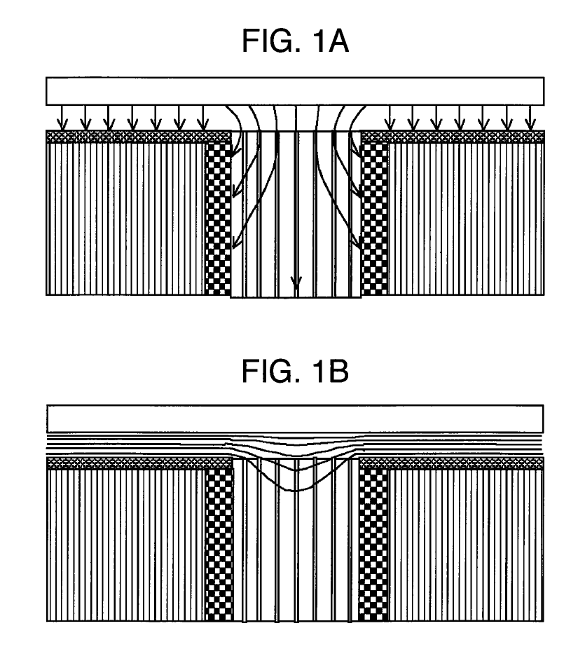

### DETAILED DESCRIPTION OF THE EMBODIMENTS

Hereafter, embodiments of the present invention will be described in detail with reference to the drawings.

### First Embodiment

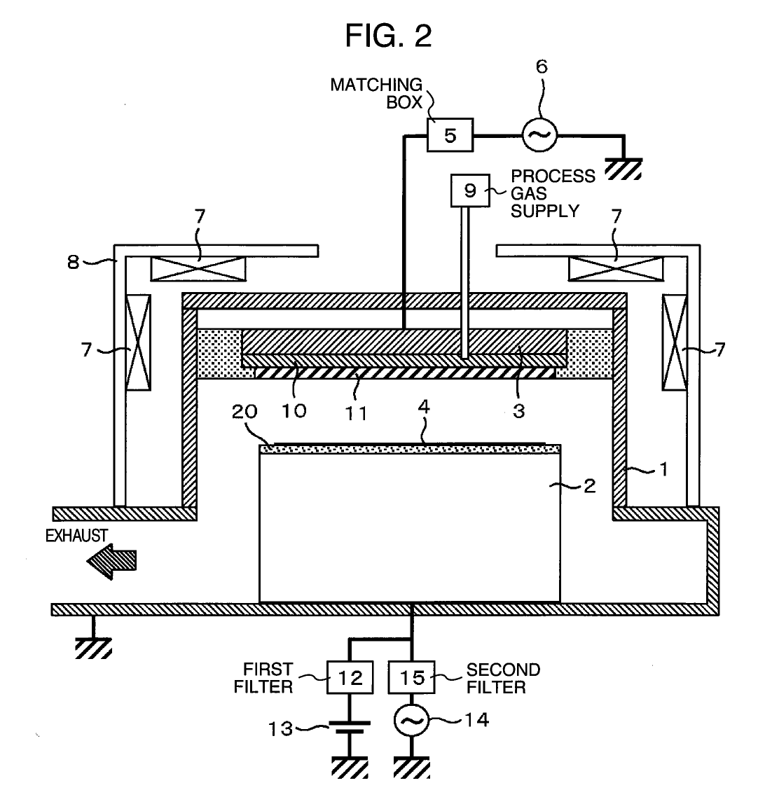

A first embodiment of the present invention will be described with reference to FIGS. 2 to 9.

FIG. 2 is a schematic view of a plasma processing apparatus according to the first embodiment of the present invention.

The plasma processing apparatus according to the present embodiment includes a plasma processing chamber (vacuum chamber) 1 provided in a vacuum processing vessel), a first electrode (sample table) 2 for mounting a member to be processed 4 which is a semiconductor wafer thereon, a second electrode 3 supplied with plasma generating high frequency power, a matching box 5, a plasma generating high frequency power supply 6, an electromagnetic coil 7, a yoke 8, a process gas supply system 9, a gas dispersion plate 10, a shower plate 11, a first filter 12, a direct current power supply (electrostatic chuck power supply) 13, a high frequency bias power supply 14, and a second filter 15.

The first electrode 2 and the second electrode 3 in the plasma processing chamber 1 constitute one pair of opposed electrodes. The first electrode 2 serves also as the sample table on which the member to be processed 4 is mounted. An electrostatic chuck plate (electrostatic chucking ceramics) 20 is disposed between the member to be processed 4 and the sample table 2. The electrostatic chuck plate 20 adsorbs the member to be processed 4 on the sample table 2. High frequency energy from the high frequency power supply 6 is supplied to the second electrode 3 via the matching box 5. The gas dispersion plate 10 connected to the process gas supply system 9 and the shower plate 11 which emits gas supplied from the gas dispersion plate 10 into the processing chamber 1 are disposed under the second electrode 3. The process gas emitted into the processing chamber 1 is converted to plasma by the high frequency energy supplied to the second electrode 3. This plasma is made uniform in the processing chamber 1 by the electromagnetic coil 7 and the yoke 8 disposed around it.

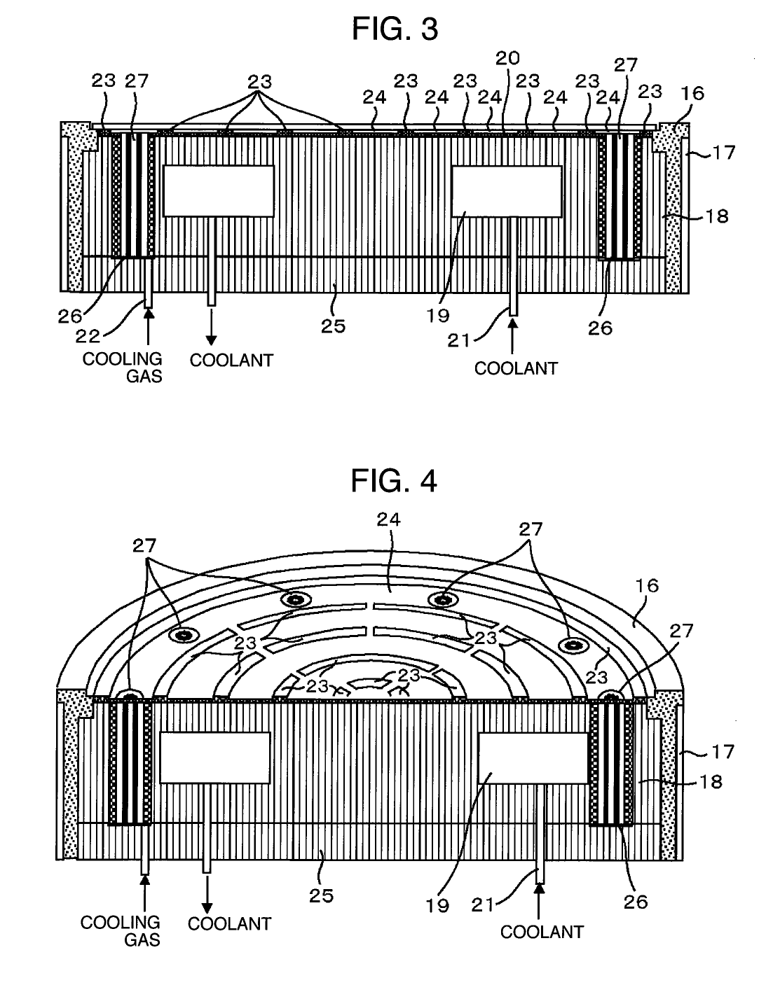

FIG. 3 is a sectional view of the first electrode 2 according to the first embodiment of the present invention.

The first electrode 2 includes mainly a susceptor 16, a cover 17, a head part (sample table) 18, a space (coolant path) 19 formed in an annular form within the head part, and a disk-shaped electrostatic chuck plate (electrostatic chucking ceramics) 20.

The head part 18 of the first electrode 2 which holds the member to be processed 4 mounted thereon takes the shape of a head. The electrostatic chucking ceramics 20 taking the shape of a disc in the same way is mounted on a top surface of the head part 14. The member to be processed 4 is mounted directly on the electrostatic chucking ceramics 20. The annular susceptor 16 made of SiO₂ is provided outside the first electrode 2. The cover 17 made of a metal and sprayed with ceramics on the surface is provided further outside the susceptor 16. The cover 17 assumes the ground potential. The head part 18 is made of aluminum. The space (coolant path) 19 for retaining a coolant to control the temperature of the head part 18 and the coolant path 21 for supplying and discharging the coolant to the space are provided in the central part. Annular island parts 23 and annular groove parts 24 are provided on the top surface of the electrostatic chucking ceramics 20.

FIG. 4 is an oblique view of the first electrode 2 according to the first embodiment of the present invention.

In the groove parts 24, a plurality of grooves are formed in the circumference direction (in a concentric circle form) and in the radial direction so as to cause the supplied heat transfer gas to spread uniformly in the gap between the member to be processed 4 and the electrostatic chucking ceramics 20 with ease.

The island parts 23 are parts left after the groove parts 24 are formed on the electrostatic chucking ceramics 20. The island parts 23 are in direct contact with the member to be processed 4, and the island parts 23 greatly contribute to adsorption of the member to be processed 4.

Means for supplying the heat transfer gas to the gap between the electrostatic chucking ceramics 20 and the member to be processed 4 will now be described with reference to FIG. 3. Heat transfer gas, such as He or Ar, introduced from a heat transfer gas supply path 22 is supplied to a heat transfer gas distribution path 26 dug on a base part 25 in a circumference direction. The base part 25 is made of aluminum in the same way as the head part 18, and the base part 25 is in electric contact with the head part 18. The heat transfer gas supplied to the heat transfer gas distribution path 26 is passed through gas hole parts 27 which penetrate the electrostatic chucking ceramics 20 and the head part 18, and supplied to the gap between the electrostatic chucking ceramics 20 and the member to be processed 4.

As shown in FIG. 4, a plurality of gas hole parts 27 are provided at equal intervals in the circumference direction in order to ensure in-plane uniformity of the heat transfer gas pressure and conductance.

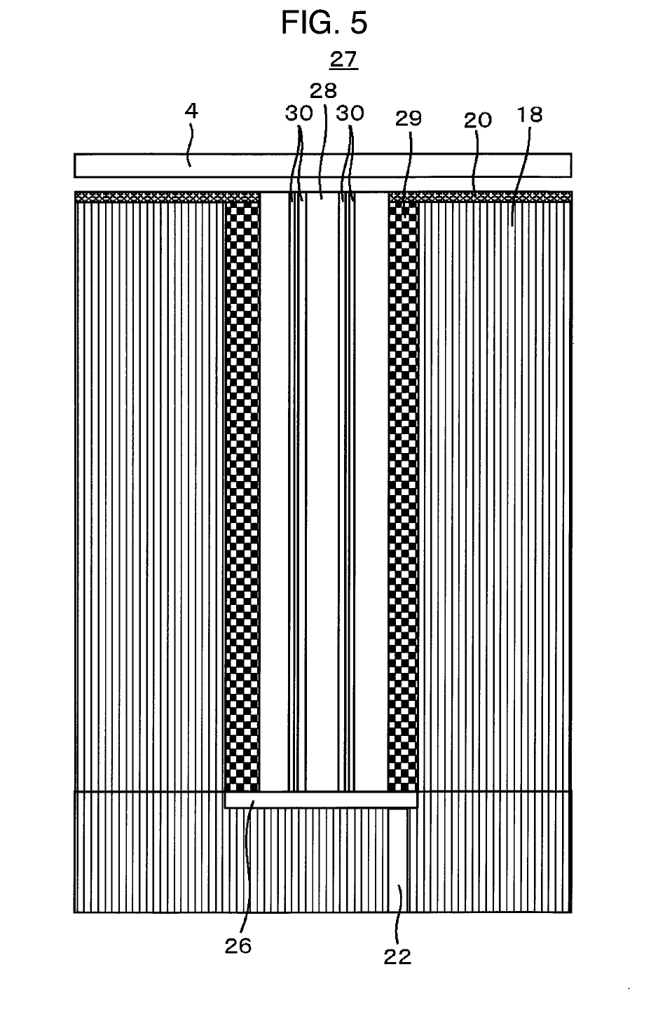

FIG. 5 is a sectional view of a gas hole part according to the first embodiment of the present invention.

The gas hole part 27 includes a boss 28, small tubes (heat transfer gas supply paths) 30 which penetrate the boss 28, and a sleeve 29 provided between the boss 28 and the head part 18. It is desirable that the boss 28 has a diameter in the range of 3 to 8 mm, and a diameter of 5.5 mm is adopted in the present embodiment. It is desirable that the sleeve 29 has a thickness in the range of approximately 0.5 to 2 mm, and a thickness of 1 mm is adopted in the present embodiment. In the present embodiment, therefore, the diameter of the gas hole part 27 becomes 7.5 mm. The length in the depth direction is equivalent to that of the head part 18. Since the boss 28 is required to have a property of withstanding high voltages, ceramics having an especially high insulation property, such as high purity Al₂O₃ or high purity Y₂O₃, is desirable. As for the sleeve 29 and the small tubes 30 as well, a material quality similar to that of the boss 28 is desirable. The gap between the sleeve 29 and the head part 18 and the gap between the sleeve 29 and the boss 28 are bonded by an insulative bonding agent. The electrostatic chucking ceramics 20 is sprayed so as to cover the top surface of the bonded head part 18 and sleeve 29. At that time, the peripheral part of the electrostatic chucking ceramics 20 and the boss 28 is sprayed leaving no space. In the case where the electrostatic chucking ceramics 20 is a sintered body, the gap between the boss 28 and the sleeve 29 is bonded by an insulative bonding agent. However, the bonding agent between the sleeve 29 and the head part 18 becomes conductive or insulative according to the electrostatic chucking method.

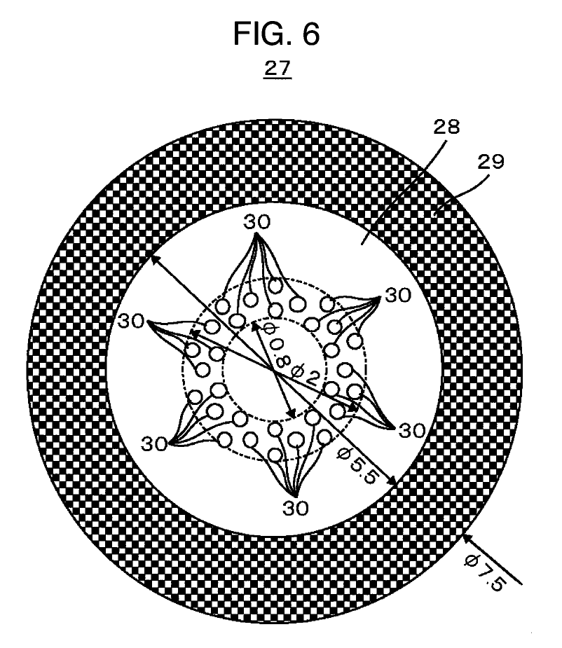

FIG. 6 is a top view of the gas hole part according to the first embodiment of the present invention.

For suppressing the abnormal discharge, it is desirable to set the diameter of the small tube 30 equal to 0.3 mm or less. This is based on the Paschen's law and that the optimum pressure region of the heat transfer gas is in the range of 100 to 10 kPa. Considering the machining property and conductance required to let flow a flow rate of the heat transfer gas, the diameter is desired to be at least 0.1 mm. In the present embodiment, a diameter of 0.2 mm is adopted.

For preventing the abnormal discharge, the small tubes 30 are disposed in the range of 10 to 50% of the radius when measured from the center of the gas hole part 27 toward the outside.

In the present embodiment, the small tubes 30 are provided in the range of 0.8 to 2 mm in diameter from the center of the boss 28 which corresponds to a range of 10.6 to 26% in diameter from the center of the gas hole part 27. As for the number of the small tubes 30, at least twenty is desirable considering the conductance. In the present embodiment, the number of thirty is adopted.

As shown in FIG. 2, the direct current power supply (electrostatic chuck power supply) 13 of several hundreds V is connected to the first electrode 2 via the filter 12 for cutting off high frequency components. As a result, the member to be processed 4 is adsorbed and held on the first electrode by the Coulomb force which acts between the member to be processed 4 and the first electrode 2 via the electrostatic chucking dielectric (electrostatic chuck film). The high frequency bias power supply 14 having a frequency in the range of 400 kHz to 4 MHz is connected to the first electrode 2 via the second filter 15 which cuts off the DC component.

When conducting processing (etching processing) on the member to be processed 4, the member to be processed 4 is introduced into the vacuum chamber 1 by a conveyance unit in a vacuum state. The member to be processed 4 is mounted on the first electrode 2 which is previously controlled in temperature by the coolant. The electromagnetic coil 7 is energized to form a predetermined magnetic field, and the process gas is introduced. The plasma generating high frequency power supply 6 is energized to generate an electromagnetic wave in a frequency region in the range of a microwave to a VHF wave from the second electrode 3 and convert the gas in the processing chamber 1 to plasma by an interaction between the electromagnetic wave and the magnetic field. After generation of the plasma, the member to be processed 4 is adsorbed on the first electrode 2 by applying a direct current voltage from the direct current power supply 13.

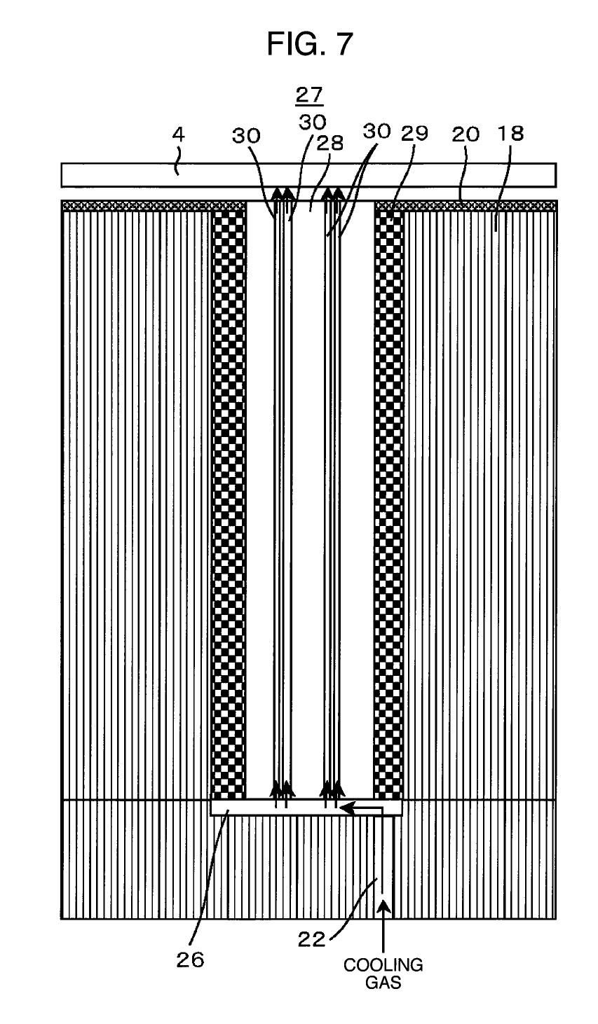

Subsequently, as shown in FIG. 7, the gap between the member to be processed 4 and the first electrode 2 (the top surface of the electrostatic chucking ceramics 20) is filled with the heat transfer gas such as helium supplied from the heat transfer gas supply path 22 through the heat transfer gas distribution path 26 and the small tubes 30. The heat transfer gas diffuses quickly and fulfils the heat transfer function. The heat transfer gas transmits heat which enters the member to be processed 4 from the plasma, to the head part 18 to implement heat exchange with the coolant.

Subsequently, the high frequency power is applied to the first electrode 2 by the high frequency bias power supply 14 in order to process the member to be processed 4. Owing to this high frequency power, a potential difference between a self-bias potential Vs generated on the member to be processed 4 and a potential Ve applied to electrostatically adsorb the member to be processed on the sample table, i.e., Vd=Vs−Ve is generated between the member to be processed and the sample table.

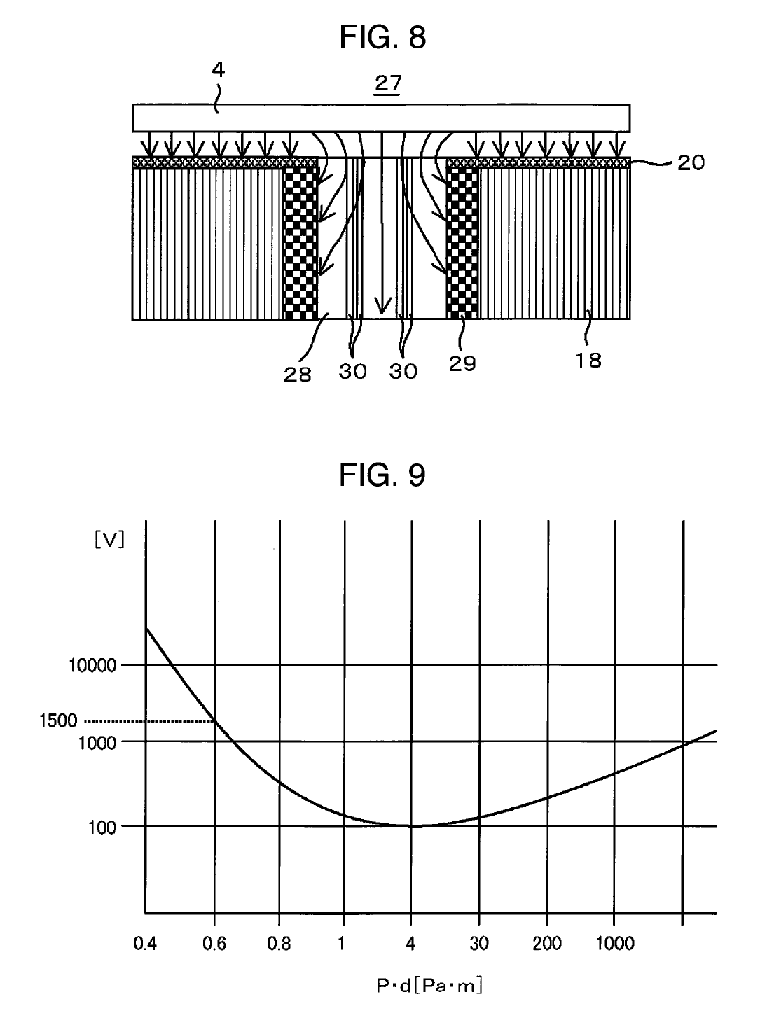

FIG. 8 is a diagram showing electric field distribution in the gas hole part according to the first embodiment of the present invention by using electric lines of force.

In the present invention, there are no gas holes near the center of the gas hole part. Therefore, electrons are not accelerated linearly in the depth direction by the electric field distribution. In other words, electrons are prevented from receiving great kinetic energy from the electric field without colliding with the side face of the small tube 30, colliding with neutral particles, and generating an electron avalanche which becomes a cause of the abnormal discharge. Furthermore, the acceleration direction of electrons in the small tube 30 has an inclination in the radial direction. Thus, the electrons are accelerated not only in the depth direction but also in the radial direction. The electrons collide with the side face and lose kinetic energy. Supposing that the acceleration distance of electrons is the discharge space, it is considered that a decrease of the acceleration distance decreases the discharge space.

Thus, according to the present embodiment, the abnormal discharge in the gas hole part 27 can be suppressed by separating the small tubes 30 from the vicinity of the center and decreasing the effective discharge space.

An example of processing conditions under which the abnormal discharge poses a problem is: the self-bias potential Vs=2,000 V, the potential Ve applied for the electrostatic chuck=−500 V, and the heat transfer gas pressure P=3,000 Pa. In this case, the potential difference generated between the member to be processed and the sample table becomes Vd=2500 V.

FIG. 9 is a diagram showing the Paschen's law which prescribes an abnormal discharge start voltage as a function of a product of the pressure and the hole diameter.

Since the hole diameter d is 0.2 mm, it follows that P·d=0.6 [Pa·m]. The abnormal discharge start voltage at that time becomes 1,500 V. Accordingly, it is considered that the abnormal discharge will be generated. If the locations of the gas holes are set equal to 50% or less of the radius when measured from the center of the gas hole part toward the outside, however, the electric field strength reduces to one-third as compared with the periphery of the gas hole part, and consequently the potential difference also becomes 1/3.840 V and the abnormal discharge can be suppressed.

In other words, unless the gas holes exist outside locations corresponding to 50% of the radius when measured from the center of the gas hole part toward the outside, where the electric field strength is strong, the abnormal discharge can be suppressed.

### Second Embodiment

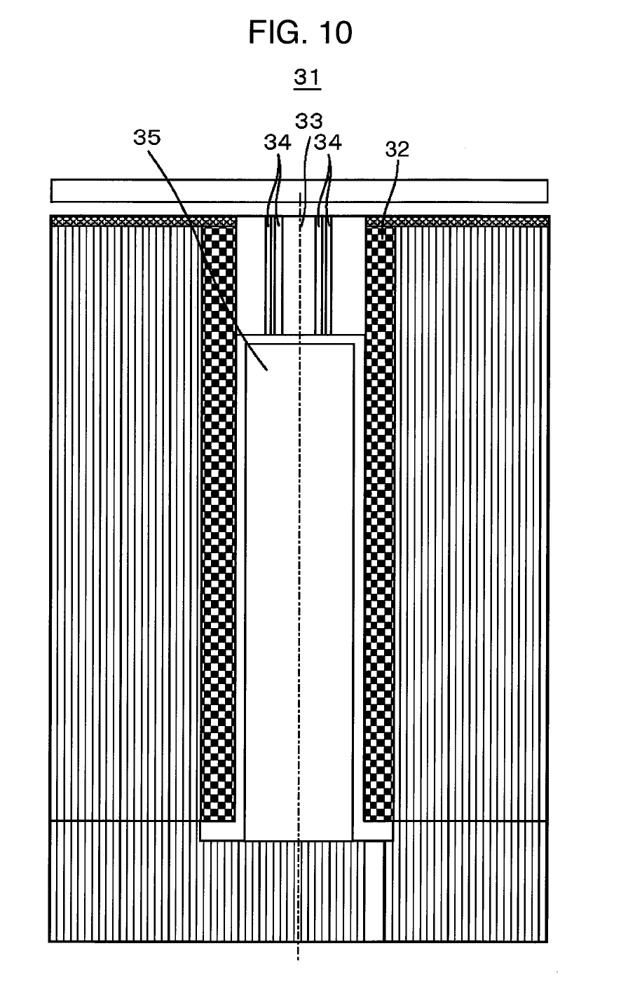

A second embodiment of the present invention will now be described with reference to FIGS. 10 to 12.

FIG. 10 is a sectional view of the gas hole part according to the second embodiment of the present invention.

A gas hole part 31 includes a sleeve 32, a boss 33, small tubes 34, and a strut 35. In the second embodiment, the strut 35 is added to the first embodiment.

The boss 33 has a diameter in the range of 3 to 8 mm and a length in the depth direction in the range of 2 to 10 mm. The small tubes 34 have a diameter of 0.2 mm. The small tubes 34 penetrate the boss 33. The strut 35 is formed of a dielectric such as ceramics in the same way as the boss 33. The strut 35 is provided under the boss 33 with a gap of 0.3 mm. Unlike the boss 33, the strut 35 takes a simple cylindrical shape and small tubes are not provided within the strut 35. The strut 35 is smaller than the inner diameter of the sleeve 32 by approximately 0.1 to 0.2 mm. The heat transfer gas flows through this gap.

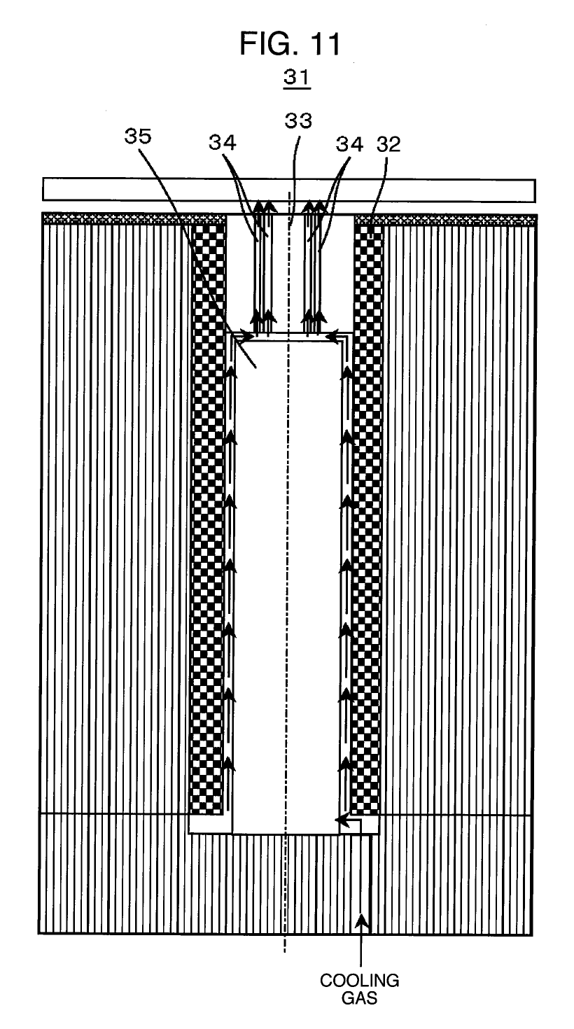

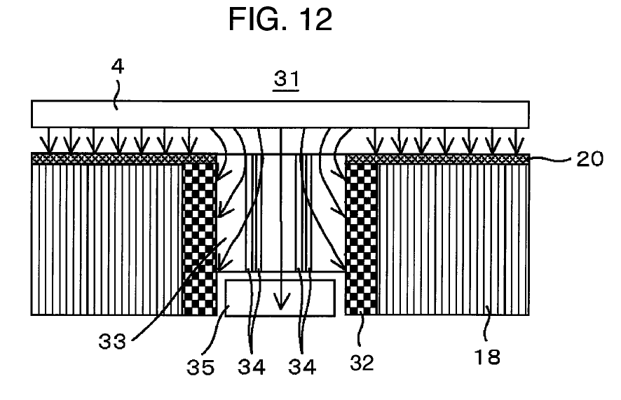

FIG. 11 is a diagram showing a flow of the heat transfer gas in the gas hole part according to the second embodiment of the present invention.

FIG. 12 is a diagram showing electric field distribution in the gas hole part according to the second embodiment of the present invention by using electric lines of force.

In this structure, electrons which have passed through the small tubes 34 collide with the strut 35. As a result, the acceleration region and the discharge space can be narrowed. In addition, the length in the depth direction can be shortened. Therefore, improvement of the conductance can be expected.

It should be further understood by those skilled in the art that although the foregoing description has been made on embodiments of the invention, the invention is not limited thereto and various changes and modifications may be made without departing from the spirit of the invention and the scope of the appended claims.

1. A plasma processing apparatus comprising:
a vacuum chamber;
a sample table for mounting a member to be processed thereon, the sample table having a coolant path to control a temperature of the member to be processed;
an electrostatic chuck power supply for electrostatically adsorbing the member to be processed on the sample table; and
a plurality of gas hole parts provided in the sample table to supply heat transfer gas between the member to be processed and the sample table and thereby control a temperature of the member to be processed,
wherein
each of the gas hole parts comprises a boss formed of a dielectric, a sleeve, and a plurality of small tubes, and
the small tubes are arranged in a range of 10 to 50% of a radius when measured from a center of the gas hole part toward outside.

2. The plasma processing apparatus according to claim 1, wherein
each of the gas hole parts further comprises a strut formed of a dielectric, and
the strut is disposed under the boss so as to form a gap between the strut and the boss and another gap between the strut and the sleeve, and the heat transfer gas flows through the gaps.
